(19) United States
(12) Patent Application Publication
(10) Pub. No.: US 2010/0112349 A1
(43) Pub. Date: May 6, 2010

(54) Nanomaterial With Core-Shell Structure

(75) Inventors: Cherng-Yuh SU, Taipei (TW); Hsuan-Ching Lin, Taipei (TW); Chung-Kwei Lin, Taichung (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: National Taipei University of Technology, Taipei (TW)

(21) Appl. No.: 12/510,816

(22) Filed: Jul. 28, 2009

(30) Foreign Application Priority Data
Nov. 5, 2008 (TW) 097142632

(51) Int. Cl. B32B 9/04; C23C 16/513; B82B 1/00; B82B 3/00

(52) U.S. Cl. 428/389; 427/576; 977/762; 977/890

(57) ABSTRACT

A nanomaterial with a core-shell structure is provided. The nanomaterial comprises a shell and a core, wherein the shell is located on at least a portion of the surface of the core. The shell is substantially composed of a first metal oxide. The core is substantially composed of a second metal oxide, while the second metal oxide is a non-stoichiometric compound. The inventive nanomaterial exhibits excellent properties, such as good gas sensitivity and better field emission property, and has a high applicability.

This application claims priority to Taiwan Patent Application No. 097142632 filed on Nov. 5, 2008, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention provides a nanomaterial with a core-shell structure. In particular, the present invention provides a nanocomposite material comprising a non-stoichiometric compound.

2. Descriptions of the Related Art

Generally, a material is deemed as a nanomaterial if at least one of its length, width, and height is in a range of nonameter scale (usually ranging from 1 nm to 100 nm). The nanomaterials can be generally divided into three types. The zero-dimensional nanomaterial has the length, width, and height in the range of nanometer scale. The one-dimensional nanomaterial has the width and height in the range of nanometer scale. The two-dimensional nanomaterial has the height in the range of nanometer scale only. For example, the zero-dimensional nanomaterial includes particle forms such as nanopowders; the one-dimensional nanomaterial includes thin bar forms such as nanowires or nanobars; and the two-dimensional nanomaterial includes plane layer forms such as nanofilms. As compared to the zero- and two-dimensional nanomaterials, the one-dimensional nanomaterial exhibits unique and excellent properties such as good field emission property due to its high specific surface area and high aspect ratio. Therefore, the one-dimensional nanomaterials have been highly valued by researchers, and it can be seen in T. Ruecks et al. Science, 289, 84 (2000) and M. H. Huang et al. Science, 292, 1897 (2001).

When the size of a well known bulk material is narrowed down to a nanoscale, its original chemical properties and physical properties, such as thermal, optical, electric, magnetic, or mechanical properties will change greatly, thereby opening a door to the field of nanomaterial applications. For example, the melting point of pure gold has a constant value (about 1064°), but as its particle size is narrowed down to a nanoscale, the melting point is no longer constant (see Ph. Buffat and J. P. Borel, Phys. Rev. A, 13, 2287 (1976)). Moreover, for example, the tungsten oxide (WO₃) nanomaterial in saturated state is very advantageous for use in electrochromatic techniques, gas sensing techniques, and photocatalysts due to its unique properties. The related teachings can be found in E. B. Franke et al. J. App. Phys. 88, 5777 (2000) and H. Kominami et al. J. Mat. Chem. 11, 3222 (2001). Furthermore, there is a research showing that the tungsten oxide material in unsaturated state (i.e., non-stoichiometric) such as W₁₈O₄₉ has a unique structure and improved properties induced by oxygen defects, while the tungsten oxide material in unsaturated state exhibits better performances in practical applications as compared with that in saturated state (see G. L. Frey et al. J. Solid State Chemistry, 162, 200 (2001)). The whole contents of the above documents are all incorporated hereinto by reference.

Although it is possible to change the size and structure of the single nanomaterial to adjust its properties, the changing level is very limited due to the original properties of the nanomaterial. Therefore, the research of composite nanomaterials (referred to as “nanocomposite materials” hereinafter) has gradually become a trend in nanotechnology developments for improving the applicability of nanomaterials.

Furthermore, the nanocomposite material combines two or more nanomaterials with different properties, and the overall characteristics of the resulting composite material can be adjusted to a certain level by selecting the amounts and species of different materials (e.g., blending inorganic materials, organic materials, crystalline materials and/or amorphous materials) and the conditions of the preparation process. The nanocomposite material not only has the original characteristics of composition materials but also exhibits more novel functions than each composition material especially in optic, electricity, and magnetism, thus greatly improving the applicability. For example, it has been reported that the nanocomposite material containing tungsten oxide (WO₃) can provide improved applicability as compared with the nanomaterial only composed of tungsten oxide (WO₃). It can be seen in P. S. Patil et al. Applied Surface Science, 252, 1643 (2005) and Md. M. H. Bhuiyan et al. JJAP, 45, 8469 (2006), which are incorporated hereinto by reference.

There are many known methods for preparing a nanocomposite material, and they can be substantially divided into two types, i.e., physical methods and chemical methods. Generally, the physical methods include, for example, chemical mechanical polishing methods and high-energy ball milling methods. The chemical methods include, for example, chemical vapor deposition methods, sol-gel methods, hydrothermal synthesis methods and template synthesis methods. The chemical mechanical polishing method and the high-energy ball milling method of the physical methods usually can make the material nanoscale with a high energy impact in a short time. However, the resulting nanomaterial has the drawbacks such as larger size, irregular shape, overly wide particle size distribution, and low purity. The chemical methods can prepare a nanomaterial with higher purity, but the preparation is time-consuming. Up to now, the chemical methods are more useful in preparing a nanocomposite material in saturated state, and most methods focus on the preparation of a nanocomposite material in the form of film. Nanocomposite materials in unsaturated state and the preparation methods thereof have not yet been disclosed.

Due to the developments of nanotechnology and the shortages of the substance characteristics of single nanomaterials, a novel nanocomposite material is highly desired in industry.

### SUMMARY OF THE INVENTION

The objective of the present invention is to provide a nanomaterial with a core-shell structure, comprising a shell and a core, wherein the shell is located on at least a portion of the core; the shell is substantially composed of a first metal oxide; and the core is substantially composed of a second metal oxide and the second metal oxide is a non-stoichiometric compound.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1A is a transmission electron microscope (TEM) photo of one embodiment of a nanomaterial in particle form in accordance with the present invention;

FIG. 1B is a scanning electron microscope (SEM) photo of one embodiment of a nanomaterial in nanowire form in accordance with the present invention;

FIG. 2 is a schematic diagram of an apparatus for a plasma arc gas condensation method;

FIG. 3A is a diagram of an energy band of a metal-vacuum interface without any applied electric field;

FIG. 3B is a diagram of an energy band of a metal-vacuum interface with an applied electric field;

FIG. 4A is an X-ray lattice diffraction (XRD) diagram of a nanowire obtained in an example of the present invention;

FIG. 4B is an energy dispersive spectrometer (EDS) spectrum of a nanowire obtained in an example of the present invention;

FIG. 4C is a high resolution transmission electron microscope image of a nanowire obtained in an example of the present invention;

FIG. 5 is a continuous dynamic curve diagram of electric resistance values of a nanowire obtained in an example of the present invention for detecting NO₂ gases with different concentrations at 200° C.;

FIG. 6 is a field-emission voltage-current curve diagram of a nanowire obtained in an example of the present invention and a W₁₈O₄₉ nanowire;

FIG. 7 is a UV light-visible light absorption spectrum of a nanowire obtained in an example of the present invention; and

FIG. 8 is a photoluminescence spectrum of a nanowire obtained in an example of the present invention.

### DESCRIPTION OF THE PREFERRED EMBODIMENT

The nanomaterial of the present invention has a core-shell structure comprising a shell and a core. The shell is located on at least a portion of the surface of the core. According to the present invention, the shell is substantially uniformly distributed over the surface of the core. Preferably, the shell is substantially uniformly distributed over all surface of the core. The shell is substantially composed of a first metal oxide. The first metal oxide may be, for example, titanium oxide, zinc oxide, vanadium oxide, tin oxide, or combinations thereof; and titanium oxide is preferred. Generally, the first metal oxide of the shell is in saturated state, i.e., a metal oxide with a formula such as TiO₂, ZnO, V₂O₅, or SnO₂.

As implied by the term, a nanomaterial with a core-shell structure according to the present invention further comprises a core in addition to the shell. The core is substantially composed of a second metal oxide which is a non-stoichiometric compound. In other words, the ratio of the metal atoms of the second metal oxide to its oxygen atoms fails to conform to the law of definite proportions, and thus, the second metal oxide is in unsaturated state. For example, FeO_{1.05} is a non-stoichiometric compound (in unsaturated state), and TiO₂ is a stoichiometric compound (in saturated state).

The second metal oxide useful in the present invention may be, for example, a non-stoichiometric tungsten oxide, a non-stoichiometric molybdenum oxide, a non-stoichiometric manganese oxide, or combinations thereof. According to one embodiment of the present invention, the second metal oxide is tungsten oxide with a formula WₐO_{b}, wherein the ratio b/a is between 2 and 3 (excluding the end-points 2 and 3) and preferably ranges from about 2.6 to about 2.9. For example, W₂₄O₆₈ or W₁₈O₄₉, preferably W₁₈O₄₉, can be used as the second metal oxide of the present invention, i.e., constituting the core structure of the nanomaterial.

According to one preferred embodiment of the present invention, the shell is composed of titanium oxide (TiO₂), while the core is composed of non-stoichiometric tungsten oxide (W₁₈O₄₉). Titanium oxide is a semiconductor material that has recently been used. Because the optical and chemical properties of titanium oxide are very stable, titanium oxide is widely used in photocatalysts and fuel cells. However, titanium oxide has an energy gap of about 3.2 eV (about 387 nm in wavelength), and thus, its applications are mostly limited to the range of UV light, thereby reducing the application efficiency. Tungsten oxide is also a widely used semiconductor material and primarily used in the electrochromatic technique, gas sensing technique, and photocatalyst. However, the performance properties of tungsten oxide cannot be further improved to correspond to the requirement of high accuracy. The W₁₈O₄₉—TiO₂ core-shell nanomaterial of the present invention has the characteristics of both titanium oxide and tungsten oxide and their drawbacks also can be retrieved by each other. Therefore, the whole application performance is improved which can be further demonstrated in the following examples.

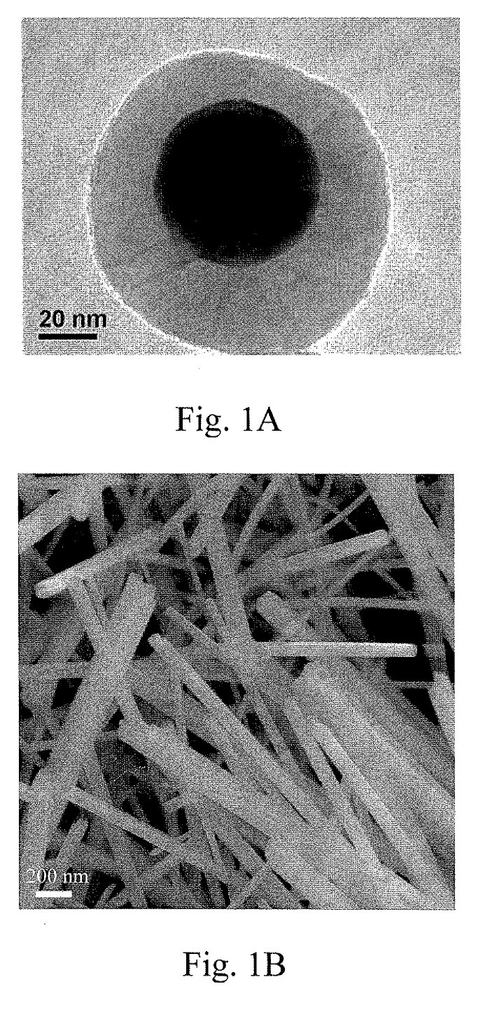

In general, the shape of the nanomaterial according to the present invention is not particularly limited. The nanomaterial may be in the form of such as a particle, a wire, a bar, a tube, a needle, a film, or a cube. FIG. 1A is a transmission electron microscope (TEM) photo of a nanomaterial in particle form in accordance with the present invention, and the photo clearly shows the core-shell structure of the nanomaterial. Furthermore, as described above, the one-dimensional nanomaterial usually exhibits more excellent physicochemical properties, and thus has higher applicability due to its high specific surface area and high aspect ratio. FIG. 1B shows another embodiment of a nanomaterial with a core-shell structure in accordance with the present invention, which is in the form of a nanowire.

The shell/core ratio of the nanomaterial in accordance with the present invention is not particular limited in principle, and usually depends on the factors such as the shape, size, and use of the desired nanomaterial. For example, the shell/core ratio of the W₁₈O₄₉—TiO₂ core-shell nanomaterial may range from about 1:1 to about 1:8 in volume.

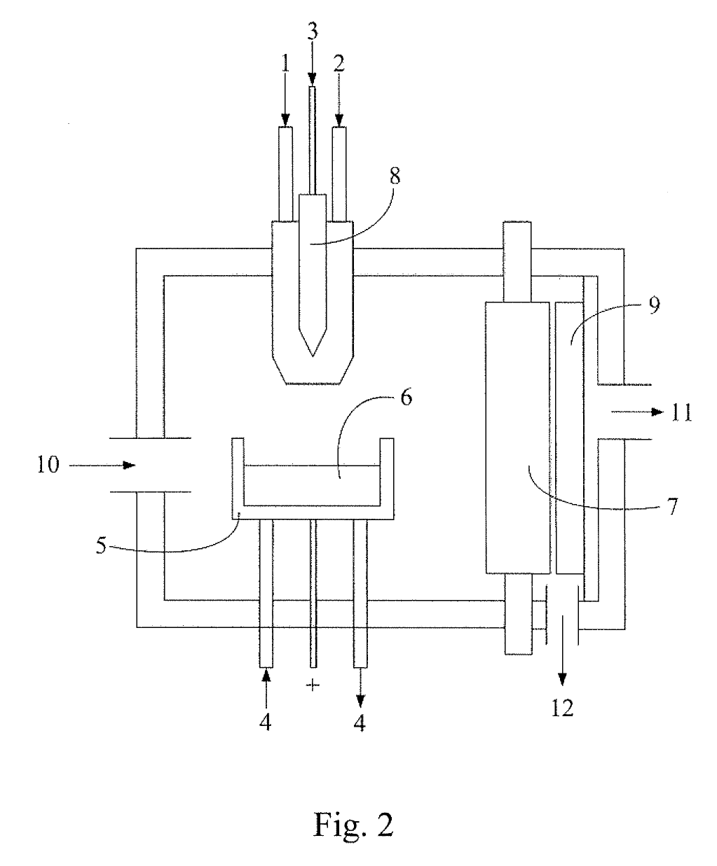

According to one embodiment of the present invention, the nanomaterial with a core-shell structure can be prepared by a plasma arc gas condensation method. Accordingly, the method may be carried out by using an apparatus schematically depicted in FIG. 2. The apparatus shown in FIG. 2 comprises a plasma gun 8, an air-blowing system 10, a crucible 5, a cooling bar 7, a scraping plate 9, and a vacuum air-extracting system 11. The theory of the plasma arc gas condensation method is mainly that the plasma gun 8 is used as a heat source to evaporate a target material 6 placed in the crucible 5 for reaction under an vacuum condition (provided by the vacuum air-extracting system 11) in the presence of an inert gas (provided by the air-blowing system 10). Then, the evaporated and reacted material condenses on a low-temperature surface and forms a nanomaterial. The air-blowing system 10 provides oxygen gas that can participate in the process reaction and/or an inert gas (e.g., argon gas or helium gas) that forms the process atmosphere. The plasma gun 8 comprises a plasma gas inlet 1, a protecting gas inlet 2, and a power supply 3. The crucible 5 comprises a pipeline for cooling water 4 passing therethrough to prevent the crucible 5 from overheating during the heating process that may adversely affect the target material 6.

More specifically, the atoms produced by heating and evaporating the target material 6 collide with inert gas atoms and rapidly lose their energy. A uniform nucleation then proceeds. Due to the convection of inert gas, the nucleating substances gradually move close to the cooling bar 7 and then accumulate at its surface to form nanomaterials. Eventually, the nanomaterials are collected into a collecting vessel 12 by using the scraping plate 9.

The suitable components and their proportions of the target material 6, and the ratio of the inert gas to the oxygen gas provided by the air-blowing system 10 depends on the requirements of the prepared nanomaterials. The ratio of the inert gas to the oxygen gas usually ranges from about 1:1 to about 100:1. For example, tungsten oxide-titanium oxide nanomaterial can be prepared by using tungsten powder and titanium oxide as the target material 6. Meanwhile, the nanocomposite materials of tungsten oxide with different oxygen contents can be prepared by controlling the ratio of the inert gas and oxygen gas provided by the air-blowing system 10. It can be seen from the above that the use of the plasma arc gas condensation method is flexible and is easy to control the experimental parameters, and thus, the method can provide various choices for preparing nanocomposite materials.

Furthermore, the core-shell nanomaterial prepared by the plasma arc gas condensation method according to the present invention has a relatively stable combining structure between the shell and the core as compared with that prepared by the general chemical method. Because the nanocomposite material prepared by the plasma arc gas condensation method has a stronger bonding and a clear interface, the composite material prepared by the process according to the present invention has the original properties of single material and also new properties thus derived.

As described above, the nanomaterial with a core-shell structure according to the present invention can provide excellent application properties. The following will further describe the gas sensing properties and the electron field emission properties of the nanomaterial in accordance with the present invention.

### (1) Gas Sensing Property

Metal oxide semiconductors (MOS) are widely used in detecting toxic gases and combustible and explosive gases because they have the properties, such as good heat resistance, good corrosion resistance and short responding time, and are easy to prepare as elements and easy to fabricate with microprocessors to form a gas sensing system or a portable detector.

When MOS is used in gas sensing detectors to detect gas, the estimation is conducted primarily by the changing level of the electrical resistance value based on the Madeling model. The related contents can be found in J. D. Levine and P. Mark Phys. Rev, 144, 751 (1996). In brief, when the gas molecules to be detected attach to the metal oxide crystal grain, a space-charge layer is formed on its surface. The higher the concentration of the gas to be detected, the thicker the space-charge layer is formed. Therefore, the electrical resistance value will be increased as the resistance for transporting electrons among the crystal grains is increased, and vice versa. Consequently, the species and the concentration of the gas to be detected can be known from the changing amount of the electrical resistance.

Thus, the properties of the gas sensing detector such as sensitivity, stability, selectivity, and reproducibility are all influenced by the factors such as the species and crystal grain properties of the used gas sensing material (i.e., MOS). The latter includes the size of crystal grain, the structure of grain boundary, and the state and defect of the crystal. Because the one-dimensional nanomaterial has a high specific surface area that increases the contact area with the gas to be detected, the one-dimensional nanomaterial is particularly useful in improving the properties of the gas sensing detector and increasing the sensitivity thereof. Therefore, the nanomaterial in the form of a nanowire in accordance with the present invention is particularly useful in the gas sensing applications.

The sensing properties of gas sensing materials can usually be determined by gas sensitivity. The gas sensitivity is defined as follows:

Sensitivity=[(Rgas−Rair)/Rair]×100%

wherein, Rair represents the electrical resistance value of the sensing material in the air and Rgas represents the electrical resistance of the sensing material in the gas to be detected. For example, the nanomaterial of the present invention has a gas sensitivity of about 1.48 for sensing about 1 ppm NO₂ gas at 200° C. Also, for example, the nanomaterial of the present invention has a gas sensitivity of about 4.18 for sensing about 4 ppm NO₂ gas at 200° C.

### (2) Electron Field Emission Property

The electron field emission is a phenomenon that under the action of a strong electric field, the energy band that transforms the electrons of a substance surface from bonded electrons into free electrons will be curved, and thus induces a quantum mechanical tunneling phenomenon of electron at the solid surface. If the applied electric field is strong enough, the electrons will tunnel through the energy barrier of the substance surface into the vacuum level. This phenomenon is called the electron field emission and can be applied in, for example, field emission displays.

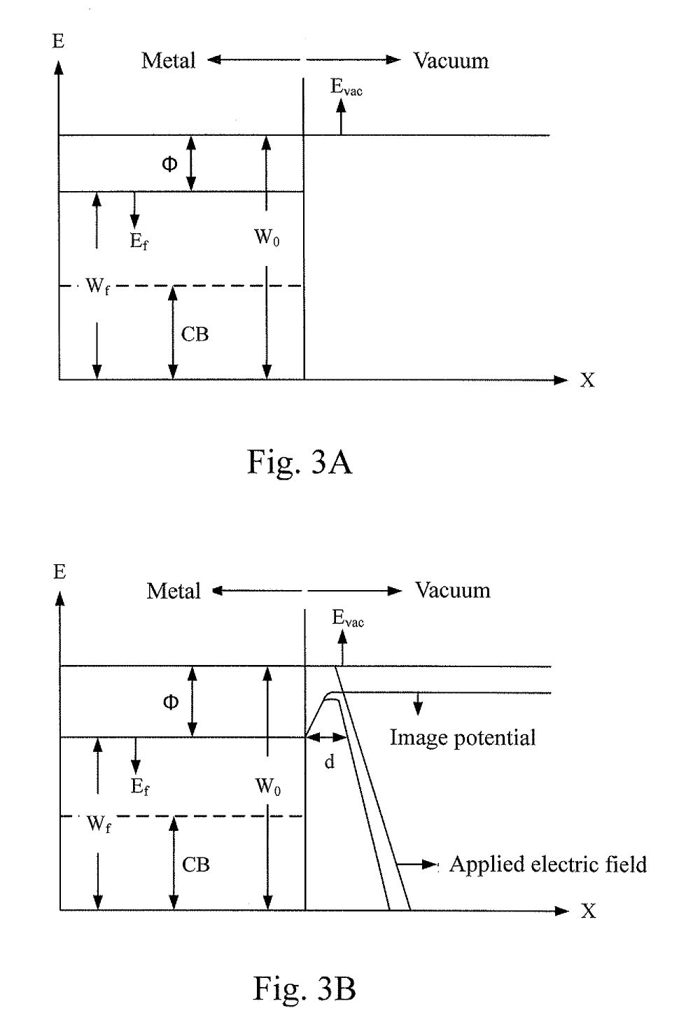

The electron field emission theory was proposed by R. H. Fowler and L. W. Nordheim in 1928 at the earliest, and its theory can be seen in FIG. 3A and FIG. 3B, wherein E_{f} represents the Fermi-level, E_{vac} represents the vacuum level, and CB represents the conductive band. The Fermi-level is the highest level occupied by the electrons in the metal at absolute zero temperature. Moreover, the work function Φ is the energy barrier that the electrons at the Fermi-level must have to overcome, and then, the electrons tunnel through the metal surface into the vacuum side. Consequently, the work function Φ is the difference between the vacuum level E_{vac} and the Fermi-level E_{f}, i.e., Φ=W₀−W_{f}.

FIG. 3A is a diagram of an energy band of a metal-vacuum interface without any applied electric field. When the applied electric field is zero, the electrons in the metal must have adequate energy (i.e., the energy more than Φ) to tunnel through the metal surface into the vacuum side, and turn into the free electrons. When applying an electric field, the action of the electric field and the conventional image potential will render the energy band to be curved, and therefore lowers the height of the energy barrier and narrows the energy barrier. It thus makes the electrons to easily tunnel through such energy barrier into the vacuum side and turns into free electrons, as shown in FIG. 3B. The distance of the energy barrier that the electrons must have to pass through will become shorter as the applied electric field becomes larger, and thus, the possibility that the electrons can tunnel through the energy barrier into the vacuum level will become higher and the resulting current will be increased.

As described above, the intensity of the applied electric field will directly influence the magnitude of the field emission current. When applied in field emission displays, the electric field at the metal-vacuum interface must be increased to obtain the adequate current. However, the operation voltage of the components also has to be increased that diverges from the low operation voltage desired in industry. Therefore, for effectively saving energy, a material that can easily emit electrons with the action of a not very strong applied electric field under vacuum condition is highly desired in the industry.

For example, the W₁₈O₄₉—TiO₂ core-shell nanomaterial of the present invention has a field emission turn-on field of less than about 2.5 V/μm and a field emission threshold field of less than about 3.5 V/μm under 2×10⁻⁶ torr. In this text, the term “turn-on field” represents the electric field required for generating a current density of 10 μA/cm², and the term “threshold field” represents the electric field required for generating a current density of 10 mA/cm².

The examples below are illustrated to further describe the present invention. However, the present invention may be embodied in other embodiments or other examples, and should not be limited to the examples provided herein.

### Example

The nanomaterial with a core-shell structure was prepared by using the apparatus shown in FIG. 2 and the process parameters listed in Table 1. Tungsten powder with a particle size of 10 μm and a purity of 99.95% and titanium oxide powder with a particle size of 10 nm and a purity of 99.95% were used. Tungsten powder and titanium oxide powder were mixed in a weight ratio of 10:1, and then placed in the crucible 5 as the target material 6. In addition, argon gas and oxygen gas were introduced into the reaction chamber in a flow ratio of 1:1 during the process, and the total gas flow in the gas-charging system was 4000 cm³/min.

TABLE 1

| Process parameter | Value |
|---|---|
| Plasma current | 90 A |
| Plasma voltage | 34 V |
| Protecting gas (Ar) | 10 SCFH |
| Plasma gas (He) | 3 SCFH |
| Cavity pressure | 760 torr |
| Gas purity (Ar or He) | 99.99% |
| Backlash value | 0.236 cm |
| Arc length | 1 cm |

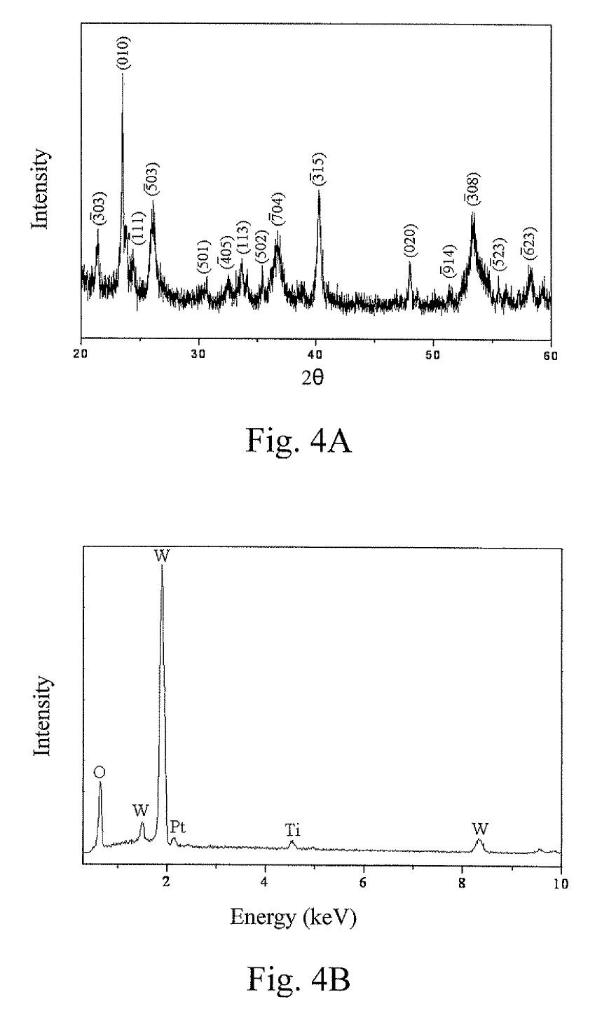

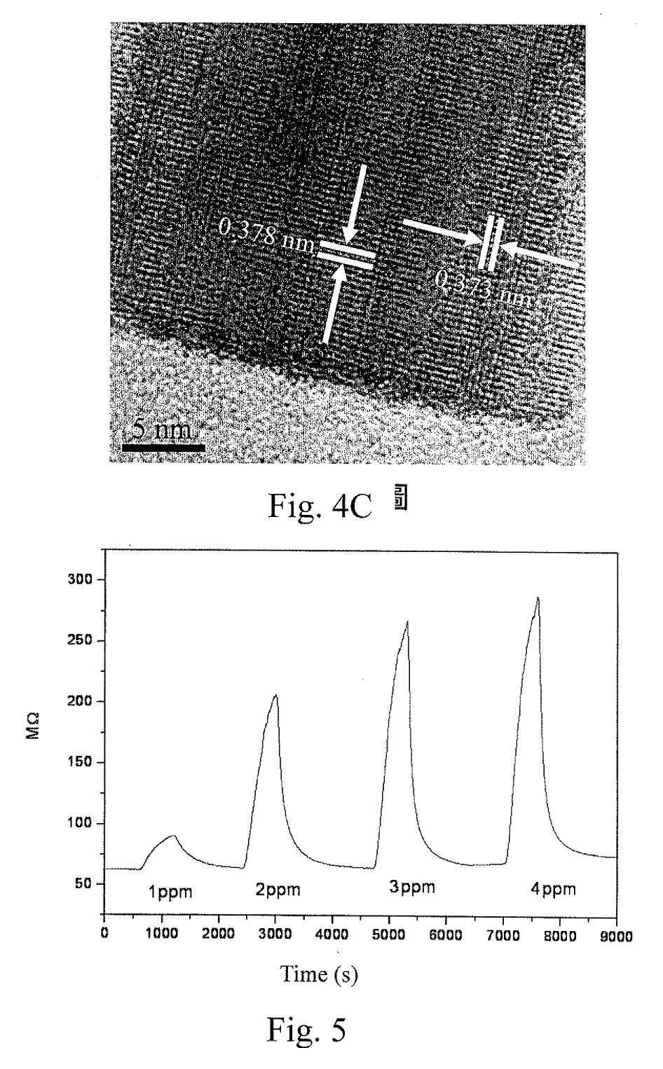

A W₁₈O₄₉—TiO₂ nanowire (referred to as “nanowire” hereinafter) with a diameter distribution of 20 nm to 100 nm was prepared, and its length could be up to several micrometers and its core-shell structure is shown in FIG. 1B, In addition, an X-ray lattice diffraction (XRD) diagram, an energy dispersive spectrometer (EDS) spectrum, and a high resolution transmission electron microscope image of the nanowire are shown in FIG. 4A, FIG. 4B, and FIG. 4C, respectively. It can be found that the resulting nanowire was composed of W₁₈O₄₉—TiO₂.

### (1) Test for Gas Sensing Property

First, the sensing substrate plated with the nanowire prepared by the example was placed into a rapid thermal annealing (RTA) furnace, and then heated to 300° C. with a rate of 5° C./minute. The temperature was held for 48 hours to facilitate the stability of the nanowire structure. The substrate was then placed into a gas sensing cavity with a flowing gas for the test.

FIG. 5 is a continuous dynamic curve diagram of electrical resistance values of the nanowire prepared by the example for detecting NO₂ gas with different concentrations (1 ppm, 2 ppm, 3 ppm, and 4 ppm) at 200° C. The electrical resistance values were increased as NO₂ gas concentration was increased, and were rapidly decreased as air being introduced into the cavity. The result indicates the excellent gas sensing property of the nanowire.

### (2) Test for Electron Field Emission Property

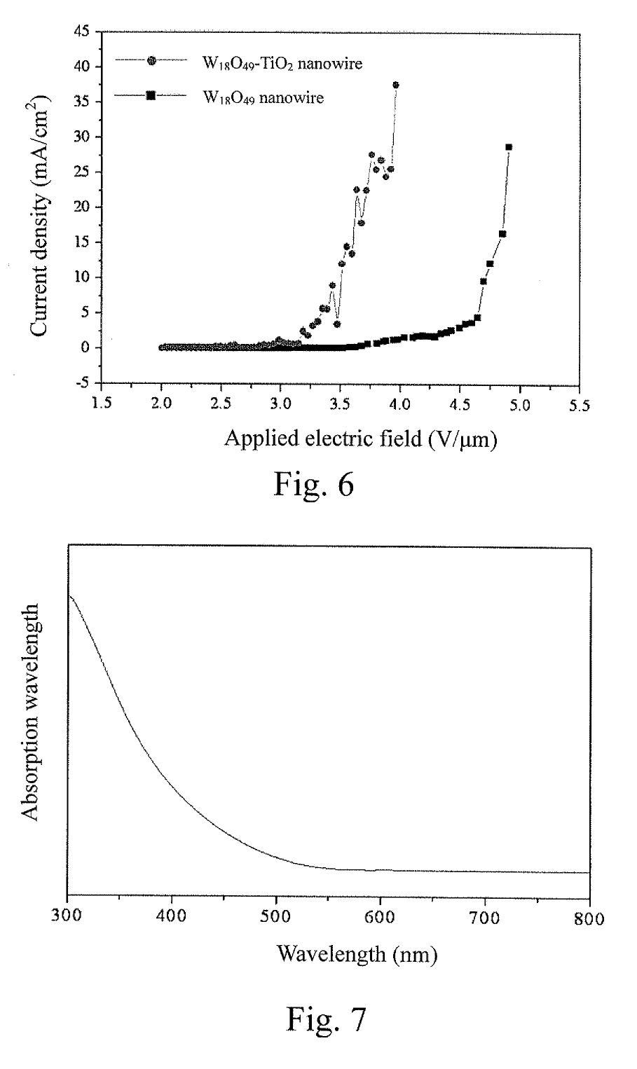

The test for electron field emission property was conducted by a transparent-anode technique and measured in a vacuum chamber with about 2×10⁻⁶ torr at room temperature. The method used the nanowire prepared by the example as a field emission source (cathode) and used an ITO conductive glass as an anode, and the distance between the cathode and the anode was set to be 250 micrometers. A field emission voltage-current curve diagram was prepared by scanning using the voltage of 0 V to 1000 V as shown in FIG. 6.

It is shown from FIG. 6 that the nanowire prepared by the example had a field emission turn-on field of about 2.2 V/μm and a field emission threshold field of about 3.38 V/μm.

The W₁₈O₄₉ nanowire, however, had a field emission turn-on field of about 4.63 V/μm and a field emission threshold field of about 6.36 V/μm. Therefore, the W₁₈O₄₉—TiO₂ nanowire according to the present invention had lower field emission turn-on field and field emission threshold field than that of the W₁₈O₄₉ nanowire, and exhibited excellent field emission properties.

### (3) Test for Optical Property

FIG. 7 is an UV light-visible light absorption spectrum of the nanowire prepared by the example. It can be seen from FIG. 7 that the absorption of the nanowire was increased greatly if the wavelength of the nanowire was less than 430 nm. This resulted in a red shift phenomenon, i.e., the phenomenon that the absorption wavelength becomes longer, as compared to the absorption edge of the WO₃ of 360 nm.

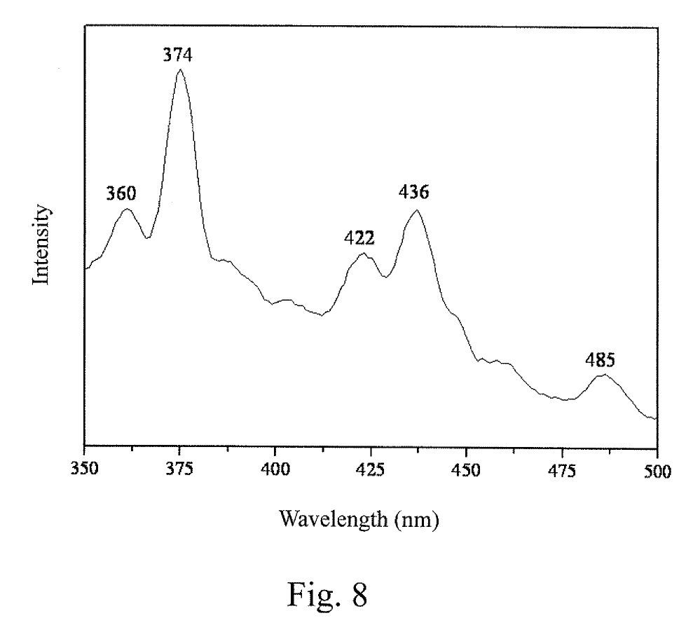

FIG. 8 is a photoluminescence spectrum of the nanowire prepared by the example that was excited by He—Cd laser with a wavelength of 275 nm. It is can be known from FIG. 8 that the resulting nanowire had an emission wavelength in the wave band of UV light (374 nm). This also resulted in a red shift phenomenon as compared to a general emission wavelength of the UV light (374 nm).

According to the above tests, the composite nanomaterial of the present invention indeed has improved properties and exhibits a high applicability.

The above disclosure is related to the detailed technical contents and inventive features thereof. People skilled in this field may proceed with a variety of modifications and replacements based on the disclosures and suggestions of the present invention as described without departing from the characteristics thereof. Nevertheless, although such modifications and replacements are not fully disclosed in the above descriptions, they have substantially been covered in the following claims as appended.

What is claimed is:

1. A nanomaterial with a core-shell structure, comprising a shell and a core, wherein the shell is located on at least a portion of the surface of the core; the shell is substantially composed of a first metal oxide; and the core is substantially composed of a second metal oxide and the second metal oxide is a non-stoichiometric compound.

2. The nanomaterial of claim 1, wherein the nanomaterial is in the form of a wire.

3. The nanomaterial of claim 1, wherein the first metal oxide is titanium oxide (TiO₂), zinc oxide (ZnO), vanadium oxide (V₂O₅), tin oxide (SnO₂), or combinations thereof.

4. The nanomaterial of claim 3, wherein the first metal oxide is titanium oxide.

5. The nanomaterial of claim 1, wherein the second metal material is tungsten oxide, molybdenum oxide, manganese oxide, or combinations thereof.

6. The nanomaterial of claim 5, wherein the second metal oxide is tungsten oxide WₐO_{b} and the ratio b/a is between 2 and 3.

7. The nanomaterial of claim 6, wherein the ratio b/a ranges from about 2.6 to about 2.9.

8. The nanomaterial of claim 1, wherein the core is substantially composed of W₂₄O₆₈ or W₁₈O₄₉.

9. The nanomaterial of claim 3, wherein the core is substantially composed of W₁₈O₄₉.

10. The nanomaterial of claim 1, having a gas sensitivity of about 4.18 for about 4 ppm NO₂ gas at 200° C.

11. The nanomaterial of claim 1, having a gas sensitivity of about 1.48 for about 1 ppm NO₂ gas at 200° C.

12. The nanomaterial of claim 9 having a field emission turn-on field of less than about 2.5 V/μm and a field emission threshold field of less than about 3.5 V/μm.

13. The nanomaterial of claim 1, wherein the nanomaterial is prepared by a plasma arc gas condensation method.
